(19) United States
(12) Patent Application Publication
(10) Pub. No.: US 2008/0026305 A1
(43) Pub. Date: Jan. 31, 2008

(54) Apparatus and method for alignment using multiple wavelengths of light

(76) Inventors: Wei Wu, Palo Alto, CA (US); William M. Tong, Palo Alto, CA (US); Jun Gao, Palo Alto, CA (US); Carl Picciotto, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/492,838

(22) Filed: Jul. 26, 2006

(51) Int. Cl. G03F 9/00; G03B 27/42; G03C 5/00

(52) U.S. Cl. 430/22; 430/30; 355/53

(57) ABSTRACT

A method and system are disclosed for aligning a lithography template having a pattern with a substrate in preparation for transferring the pattern to a surface of the substrate. The system includes an optical imaging system adapted to image a first alignment structure formed on a top surface of the template using light of a first wavelength and a second alignment structure formed on a top surface of the substrate using light of a second wavelength.

### BACKGROUND

Lithography can be used to transfer a pattern from a template (or mask) to a substrate (or one or more layers formed on the substrate). By using lithography in conjunction with additional processing steps (e.g., deposition and etch) multiple layers can be built up on a substrate to form integrated circuits or other devices. The substrate is a semiconductor wafer.

Lithography apparatus can comprise an optical system (i.e., optical lithography) or a nano-imprint system (i.e., nano-imprint lithography). Optical lithography, for example, can be used to pattern one or more layers formed on a substrate. In optical lithography, projection optics are used to project and focus radiation from a light source through a mask or reticle and onto a photosensitive (e.g., photoresist) layer that is formed on the top surface of one or more layers to be patterned. The exposed photoresist layer is developed (e.g., using a wet developer) to form a desired pattern in the photoresist layer. Subsequent etch processing (e.g., wet etching or dry plasma etching) can remove layer(s) of material at areas where the photoresist layer was removed by the developing process, but not at areas underlying where the photoresist remains. Thus, the pattern formed in the mask or reticle can be transferred to the substrate or to one or more layers of material overlying the substrate.

Optical lithography can comprise projection alignment printing, wherein typically a majority of the surface of the substrate is printed simultaneously, or stepper printing, wherein discrete areas (e.g., individual product die) are printed in succession.

An exemplary light source that can be used in optical lithography is a mercury lamp. In addition to the light source, the projection optical system can comprise an aperture, a collimating lens, and a focusing lens. In an exemplary optical lithography method, light passes from a mercury lamp through the aperture and is collimated by passing through the collimating lens. The collimated light passes through the mask or reticle, and is focused via the focusing lens onto the nano-imprint resist layer. In subsequent steps the nano-imprint resist layer can be developed and the exposed layers etched.

Nano-imprint lithography can be used to pattern one or more layers formed on a substrate. In nano-imprint lithography, a template or mold is used to imprint (e.g., emboss) a nano-imprint resist layer to form thin regions of nano-imprint resist corresponding to the pattern formed in the template. After the template is removed from the nano-imprint resist layer, the nano-imprint resist is processed (e.g., etched) such that the thin portions of the nano-imprint resist layer are removed exposing the underlying layer. Continued etching will replicate the pattern in the layer(s) formed under the nano-imprint resist layer. The formation of patterned thin films on a substrate using nano-imprint lithography is disclosed in U.S. Pat. Nos. 6,309,580 and 5,772,905 and in U.S. Patent Application Publication No. 2004/0120644, the entire contents of which are disclosed herein by reference.

The formation of a complete structure such as an integrated circuit may involve a plurality of deposition (e.g., chemical vapor deposition or sputter deposition), patterning (i.e., lithography and etch) and/or planarizing (e.g., chemical mechanical polishing) steps wherein a plurality of patterned layers can be formed in succession. In order to control the registry of each successive layer, alignment of the template and the substrate precedes each lithographic step. The precision and accuracy of both optical lithography and nano-imprint lithography are a function of the alignment between the template and the substrate. Alignment structures (e.g., alignment marks) formed on the template and on the substrate can be used to align the template with respect to the substrate prior to lithography.

### SUMMARY

Disclosed is a method for aligning a lithography template comprising a first alignment structure with a substrate comprising a second alignment structure, the method comprising (i) simultaneously illuminating the first alignment structure and the second alignment structure with light; (ii) forming a first optical image of the first alignment structure with a first wavelength of the light; (iii) forming a second optical image of the second alignment structure with a second wavelength of the light; and (iv) aligning the template with the substrate by adjusting minimizing the relative displacement of the first and second optical images.

An alignment apparatus for aligning a lithography template comprising a first alignment structure with a substrate comprising a second alignment structure comprises (i) means for simultaneously illuminating the first alignment structure and the second alignment structure with light; (ii) means for forming a first optical image of the first alignment structure using a first wavelength of the light; (iii) means for forming a second optical image of the second alignment structure using a second wavelength of the light; (iv) means for determining the relative position of the first alignment structure and the second alignment structure; and (v) means for adjusting the relative position of the lithography template and the substrate based on the relative position of the first and second alignment structures.

### BRIEF DESCRIPTION OF THE DRAWINGS

The following detailed description of preferred embodiments can be read in connection with the accompanying drawings in which like numerals designate like elements and in which:

FIG. 1 shows an exemplary lithography alignment apparatus.

### DETAILED DESCRIPTION

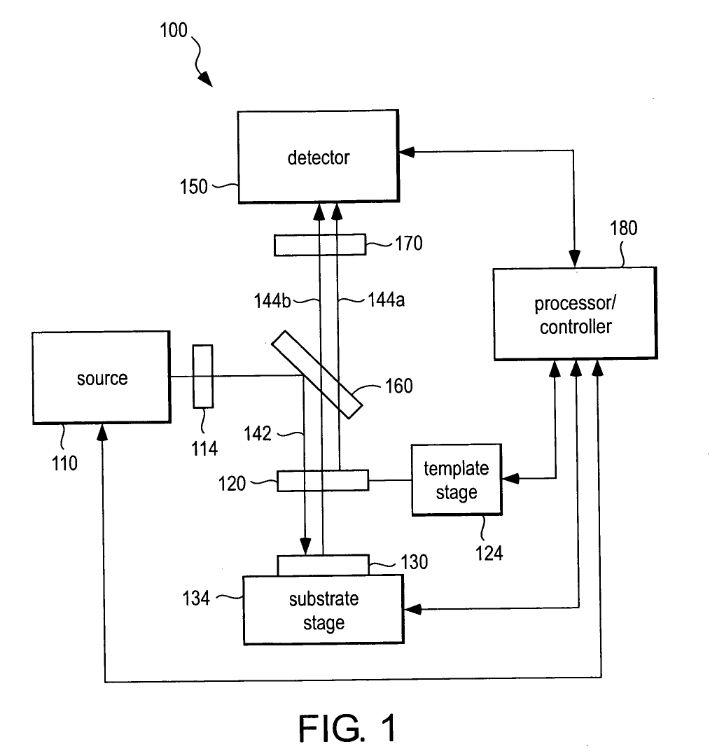

FIG. 1 shows a schematic illustration of an exemplary alignment system, or apparatus 100 for aligning a lithography template having a first alignment structure with a substrate having a second alignment structure. The apparatus comprises means, such as one or more alignment light sources 110, for producing light at any desired alignment wavelengths. The light sources 110 (i.e., from the same or from different light sources) are arranged to simultaneously illuminate a template 120 and a substrate 130 with light 142 (e.g., visible light, or non-visible light such as infrared). The light sources optionally comprise an optical filter 114 (e.g., a wavelength-selective filter) for controlling the wavelength of light used to illuminate the template and substrate, and an optical fiber or other suitable light conducting means (160) for conducting light from the light source.

The template 120 is mounted on a template stage 124. In an exemplary embodiment, the template stage is adapted to move the template along a single axis in a plane parallel to that of the movement of the substrate stage. The substrate 130 is mounted on a substrate stage 134, and can be moveable in both x-y directions, and in rotation, θ. The template stage 124 and the substrate stage 134 are controlled by processor/controller 180.

Illumination light that is radiated to the template and to the substrate illuminates the alignment structures formed thereon. The light that is reflected from the template surface and substrate surface travels through an optical path and is incident on a detector 150. The template 120 can be configured to permit incident light 142 to pass through the template in an amount sufficient to illuminate the surface of the substrate, and to allow light reflected from the substrate 144b to pass through the template in an amount sufficient to form an optical image of the alignment structure formed on the substrate.

A detecting means, such as detector 150 can be configured, for example, as a coordinate-locating camera, and can be arranged to receive reflected light 144. The light can be light, reflected from a top surface of the template (144a) and light reflected from a top surface of the substrate (144b). A coordinate-locating camera can comprise, for example, a charge coupled device (CCD) or CMOS sensor cooperating with the processor/controller 180. Alignment structures formed on the template and on the substrate can be aligned based on images formed from the light received at the detector 150. The detector can be adapted to capture images of the alignment structures in such a manner that coordinates of the alignment structure can be determined in order to perform the alignment.

The alignment light 142 (i.e., illumination light) can be directed to illuminate the entire template 120 or a portion of the template. Correspondingly, the alignment light can be directed to illuminate the entire substrate 130 or a portion of the substrate (e.g., an individual die). Similarly, the detector 150 can be adapted to receive light 144 from a selected area. For example, one or more optical devices 160 such as lenses or mirrors can be provided to focus reflected light from a selected area of the template/substrate.

The detector can comprise one or more optical filters 170. The optical filters can be configured to filter certain wavelengths of light reflected from the template and/or the substrate to form a first optical image (e.g., an optical image of an alignment structure formed on the template) and a second optical image (e.g., an optical image of an alignment structure formed on the template) such that the contrast between the first optical image and the second optical image exceeds a predetermined threshold.

A determining means, such as processor/controller 180, can be used to control various aspects of the alignment apparatus. The processor/controller can control the light source(s) and/or detector to determine to which regions illumination light is directed and/or from which regions reflected light is detected. The processor/controller can be used to control the wavelength(s) of illumination light used to illuminate the template and the substrate and/or the filtration of reflected light used to form first and/or second optical images. The processor/controller can be used to determine (e.g., calculate) the relative position (i.e., displacement) of the first and second optical images and thus the relative position of the first and second alignment structures. The processor/controller can also be used to adjust the relative position of the lithography template and the substrate based on the relative position of the first and second alignment structures in order to, for example, decrease the magnitude of their relative displacement.

A lithography process is disclosed for aligning a lithography template (e.g., mask, reticle or mold) and a substrate to, for example, prepare for transferring a predetermined pattern (based on a mask layout) from the template to the substrate or one or more layers formed on the substrate. The method can be performed using the FIG. 1 system. The method and apparatus can be used to manufacture structures, such as semiconductor devices or other devices such as liquid crystal displays or charge coupled devices, and are suitable for sub-micron alignment in ultra-violet (UV) or deep-UV lithography systems, and in nano-imprint lithography systems.

One or more alignment structures can be formed in or on a surface of the template. One or more alignment structures can be formed in or on a surface of the substrate. An alignment structure formed on the template and a corresponding alignment structure formed on the substrate can be imaged and aligned and the images can be used to align the template with respect to the substrate.

An exemplary apparatus comprises an optical imaging system adapted to image a first alignment structure formed on a top surface of the template using light of a first wavelength and a second alignment structure formed on a top surface of the substrate using light of a second wavelength. The first wavelength of light is different than the second wavelength of light. The first wavelength of light is selected so as to provide optical enhancement of the first alignment structure with respect to the second alignment structure, and the second wavelength of light is selected so as to provide optical enhancement of the second alignment structure with respect to the first alignment structure. By providing optical enhancement of one alignment structure with respect to the other, one alignment structure need not be moved to image the other. Using two different wavelengths of light to image the first and second alignment structures, both the template and the substrate can remain in the field of view of the optical imaging system during the alignment.

Data from the optical images of the alignment structures can be used to determine their relative position. By adjusting the relative displacement between the first and second alignment structures to a desired value (for example, a value from zero to any desired displacement as a function of mask layout), the template and the substrate can be aligned and the pattern formed on the template can be accurately and precisely transferred to the substrate.

The template can comprise a mask or reticle used in optical lithography, or a mold used in nano-imprint lithography. The template can include a pattern region in which a circuit pattern or other pattern to be printed on the substrate is formed, and at least one alignment structure to be used for alignment of the template with respect to the substrate. The alignment structure can be any suitable geometric shape such as a line, star, cross, dagger, “L” or “T”. The alignment structure formed on the template may or may not be part of a circuit pattern.

The template can be mounted (e.g., by attraction) on a moveable template stage. Motion of the template stage (e.g., translational and/or rotational motion) can be controlled by a controlling means such as a drive control system that controls a driving mechanism such as a motor. A processor/controller can be used to control the controlling means.

The substrate can be a semiconductor substrate such as a silicon wafer or a glass substrate used to form a flat panel display. One or more layers of material may be formed on a top surface of the substrate. In an exemplary embodiment, a layer of nano-imprint resist is formed over the substrate. A refractive index of a top (e.g., exposed) surface of the template can be different (that is, any suitable difference including, but not limited to, at least ±10%, or lesser or greater) than a refractive index of a top (e.g., exposed) surface of the substrate.

At least one alignment structure is formed in or on a surface of the substrate the alignment structure being substantially identical in size and dimension to an alignment structure of the template (that is, sufficiently matched as to achieve a desired alignment accuracy as measured, for example, empirically in patterns transferred to substrates). The alignment structures can be used for alignment of the substrate with respect to the template. The alignment structure formed on the substrate can be a via or trench formed in a layer of a device, or any other suitable geometric shape such as a line, star, cross, dagger, “L” or “T”. An alignment structure can be formed on the top surface of the substrate (or on a layer formed thereon), or, for example, an alignment structure can be formed in (e.g., etched in) the top surface of the substrate (or in a layer formed thereon). The alignment structure can be formed during the lithographic and etch processes that are used to form elements of a device. The alignment structure can, but need not be, part of the device.

The substrate can be mounted (e.g., by attraction) on a moveable substrate stage. Motion of the substrate stage (e.g., translational and/or rotational motion) can be controlled by a controlling means such as a drive control system that controls a driving mechanism such as a motor. A processor/controller can be used to control the controlling means.

In an exemplary embodiment, the size and dimension of an alignment structure formed on the template is substantially identical to the size and dimension of an alignment structure formed on the surface of the substrate. In a further exemplary embodiment, the shape of an alignment structure formed on the template is substantially identical to the shape of an alignment structure formed on the surface of the substrate (i.e., one alignment structure is a magnified version of the other).

When illuminated by white light, both the top surface of the template and the top surface of the substrate have a characteristic color. As used herein, characteristic color is the color of a surface when illuminated by white light at normal incidence. In an exemplary embodiment, the characteristic color of the template is different than the characteristic color of the substrate. In a further exemplary embodiment, the refractive index of the top surface of the template is different (e.g., at least 10% different) than the refractive index of the top surface of the substrate.

A method as disclosed herein can be used for aligning a template with a substrate. The template comprises a first alignment structure and the substrate comprises a second alignment structure. The method comprises (i) simultaneously illuminating the first alignment structure and the second alignment structure with light for example visible light or infrared light or light of any suitable wavelength or wavelengths); (ii) forming a first optical image of the first alignment structure with a first wavelength of the light (that is, a single wavelength or plurality (that is, a group) of wavelengths); (iii) forming a second optical image of the second alignment structure with a second wavelength of the light (that is, a single wavelength or plurality (that is, a group) of wavelengths); and (iv) aligning the template with the substrate by adjusting the relative displacement of the first and second optical images to a desired value (for example, zero or any desired displacement as a function of mask layout of the template).

According to an exemplary method, the template and the substrate can be illuminated (e.g., simultaneously illuminated at, or sufficiently near, the same time to achieve the results described herein) with light comprising a plurality of wavelengths (e.g., white light). Light that is reflected from the template and the substrate can be filtered to form optical images of the alignment structures. An optical image of the alignment structure formed on the template can be formed from reflected light that is filtered using a first filter. An optical image of the alignment structure formed on the substrate can be formed from reflected light that is filtered using a second filter.

The reflectivity of the top surface of the template will vary as a function of the wavelength(s) of the alignment light. Likewise, the reflectivity of the template will vary as a function of the wavelength(s) of the alignment light.

In an exemplary embodiment, light reflected from the template and the substrate can be filtered (e.g., optically filtered and/or digitally filtered) so as to form a first optical image from reflected light that is filtered with a first filter and a second optical image that is filtered with a second filter such that the contrast between the first optical image and the second optical image exceeds a predetermined threshold (that is, any suitable threshold established, for example, empirically, in advance, to provided a desired contrast).

According to another exemplary method, the template and the substrate can be illustrated (e.g., illuminated simultaneously) with a first wavelength of illumination light and then subsequently illuminated simultaneously with a second wavelength of illumination light. The reflected light can be used to form optical images of the alignment structures. An optical image of an alignment structure formed using reflections of the first wavelength of illumination light. An optical image of an alignment structure formed on the substrate can be formed using reflections of the second wavelength of illumination light.

Optical images of the respective alignment structures can be formed from linear combinations of the reflected light. For example, reflections of the first wavelength of illumination light and reflections of the second wavelength of illumination light can be combined (e.g., added or subtracted in any suitable combination) to form the first optical image, the second optical image, or both.

In an exemplary embodiment, the first and second alignment structures can be illuminated with a first wavelength of illumination light, and then illuminated with a second wavelength of illumination light (that is, a single wavelength or group of wavelengths), wherein the reflections of the first wavelength of illumination light and the reflections of the second wavelength of illumination light are combined to form the first optical image and/or the reflections of the first wavelength of illumination light and the reflections of the second wavelength of illumination light are combined to form the second optical image.

In an exemplary embodiment, the wavelengths of illumination light can be selected such that the contrast between the first optical image and the second optical image exceeds a predetermined threshold.

The amount of reflected light is a function of the angle of incidence, the index of refraction and thickness of the layer(s) from which it is reflected. The template and the substrate can be illuminated with light at normal incidence or non-normal incidence.

The substrate and the template can be aligned by adjusting the position of the substrate, the template, or both, in order to adjust the relative displacement between a reflected light signature (e.g., optical image) of an alignment structure on the substrate and a reflected light signature (e.g., optical image) of an alignment structure on the template to a desired value (e.g., zero to any desired displacement as a function of mask layout).

By adjusting the relative displacement between the first and second alignment structures, the template and the substrate can be aligned and the pattern formed on the template can be accurately and precisely transferred to the substrate. The steps of illuminating, forming and aligning can be repeated until the relative displacement of the first and second optical images is less than a pre-determined value.

An exemplary apparatus for aligning a lithography template comprising a first alignment structure with a substrate comprising a second alignment structure comprises (i) means for simultaneously illuminating the first alignment structure and the second alignment structure with light (for example, visible light or infrared light or light of any suitable wavelength or wavelengths); (ii) means for forming a first optical image of the first alignment structure using a first wavelength of the light (that is, of a single wavelength or group of wavelengths); (iii) means for forming a second optical image of the second alignment structure using a second wavelength of the light (that is, of a single wavelength or group of wavelengths); (iv) means for determining the relative position of the first alignment structure and the second alignment structure; and (v) means for adjusting the relative position of the lithography template and the substrate based on the relative position of the first and second alignment structures to a desired value (e.g., zero to any desired displacement as a function of a mask layout).

Exemplary means for illuminating the alignment structures include one or more light sources capable of producing light at two or more alignment wavelengths. The light source(s) used for illumination (i.e., alignment) may be part of an apparatus for patterning the nano-imprint resist layer, or the light source(s) may be provided separately. The light from the illumination sources can have a wavelength that does not substantially chemically or physically change the nano-imprint resist that is formed on a top surface of the substrate. In other words, the alignment light does not comprise light having a patterning wavelength relative to the materials chosen.

Exemplary means for forming optical images of the first and second alignment structures include a camera such as a coordinate-locating camera. The relative displacement between an alignment structure formed on the template and a corresponding alignment structure formed on the substrate can be determined using image detection software in conjunction with a displacement sensing algorithm.

Exemplary means for determining the relative position of the first alignment structure and the second alignment structure can include an image displacement sensing algorithm. Using an image displacement sensing algorithm, a first matrix Mₜ(x,y) corresponding to the first optical image and a second matrix Mₜ+Δt(x,y) corresponding to the second optical image can be processed to compute a displacement vector ΔM between them. For an exemplary embodiment, the image displacement sensing algorithm can be selected to assume that the features and/or textures of the second optical image do not change over the interval Δt (i.e., a rigid body assumption). A suitable image displacement algorithm can include, for example, an image cross-correlation algorithm or other displacement estimation algorithm. Details of exemplary image cross-correlation algorithms are disclosed in commonly-owned U.S. Pat. Nos. 6,195,475 and 5,149,980, the disclosures of which are hereby incorporated by reference in their entirety.

Exemplary means for adjusting the relative position of the lithography template and the substrate include a moveable substrate stage upon which the substrate can be mounted. A processor/controller can be used to control the motion of the substrate stage. In order to align the template with the substrate, the position of the substrate can be changed while the position of the template is held fixed. It will be appreciated, however, that the template and the substrate can be aligned by changing the position of the template, the substrate, or both.

It will be appreciated that for a template comprising a top surface having a first characteristic color and a substrate comprising a top surface having a second characteristic color, the illumination wavelength(s) used to illuminate both surfaces (e.g., simultaneously) can be selected to visually enhance alignment structures formed on one surface with respect to the other surface. Thus, the illumination wavelength can be toggled between two different wavelengths to produce a first image, wherein the image of an alignment structure formed on the template is emphasized with respect to an alignment structure formed on the substrate, and a second image, wherein the image of an alignment structure formed on the substrate is emphasized with respect to an alignment structure formed on the template. Similarly, filters can be selected to visually emphasize an alignment structure formed in one surface with respect to the other surface when both surfaces are simultaneously illuminated with white light, or any suitable light source. Thus, the filtration can be toggled to produce a first image, wherein the image of an alignment structure formed on the template is emphasized with respect to an alignment structure formed on the substrate, and a second image, wherein the image of an alignment structure formed on the substrate is emphasized with respect to an alignment structure formed on the template.

The color of an object can be a function of the wavelength(s) of light reflected by the object. For example, an object that appears red when illuminated with white light appears red because red light is reflected from the object (i.e., the object absorbs light at wavelengths corresponding to the primary colors blue and green). Similarly, an object that appears blue when illuminated with white light appears blue because blue light is reflected from the object (i.e., the object absorbs light at wavelengths corresponding to the primary colors red and green). Because the first and second alignment structures are formed in or on different color surfaces (when viewed under white light), the illumination wavelength (or filtration) can be selected to emphasize one alignment structure with respect to the other.

By way of example, the characteristic color of a top surface of an exemplary template can be red, and the characteristic color of a top surface of an exemplary substrate can be blue. The image of the template can be emphasized with respect to the image of the substrate by illuminating the template and the substrate with light that is not red (e.g., blue light). Similarly, the image of the substrate can be emphasized with respect to the image of the template by illuminating the template and the substrate with light that is not blue (e.g., red light). The colors of the incident illumination light can be selected to provide an image of an alignment structure formed on the template and an image of an alignment structure formed on the substrate wherein the two images can be distinguished by a detector cooperating with a processor/controller.

Contrast enhancement to achieve a desired contrast level between the template and the substrate can be achieved by filtering the light reflected from the template and the substrate. Illumination light comprising a plurality of wavelengths (e.g., white light) can be used to illuminate the field (or a portion of the field). The light reflected from both the template and the substrate can be filtered using a first filter and a second filter. The filters can comprise optical filters (e.g., color filters) that lie in the optical path of the reflected light. For example, the filters can be located in front of the detector/camera. Alternatively, filtration of the reflected light can be performed electronically.

If the (characteristically red) template and the (characteristically blue) substrate are simultaneously illuminated with white light, the image of the template can be emphasized with respect to the image of the substrate by filtering the reflected light with a blue filter. Similarly, the image of the substrate can be emphasized with respect to the image of the template by filtering the reflected light with a red filter. The reflected light can be filtered so as to provide an image of an alignment structure formed on the template and an image of an alignment structure formed on the substrate wherein the two images can be distinguished by a detector cooperating with a processor/controller.

In an exemplary embodiment illustrating the use of filtration, the image of a first alignment structure can be emphasized with respect to the image of a second alignment structure by forming an optical image using only reflected light having a wavelength corresponding to the characteristic color of the first alignment structure. Thus, if a characteristically red template and characteristically blue substrate are simultaneously illuminated with white light, the image of an alignment structure formed on the template can be emphasized with respect to an image of an alignment structure formed on the substrate by filtering the reflected light such that only red light is used to form the optical image.

A first filter can be selected such that the wavelength of light used to form the first optical image is substantially equal (for example ±10% or less or greater as desired) to the wavelength of light corresponding to the characteristic color of the first alignment structure and/or a second filter can be selected such that the wavelength of light used to form the second optical image is substantially equal (for example ±10% or less or greater as desired) to the wavelength of light corresponding to the characteristic color of the second alignment structure.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

1. A method for aligning a lithography template comprising a first alignment structure with a substrate comprising a second alignment structure, the method comprising:
simultaneously illuminating the first alignment structure and the second alignment structure with light;
forming a first optical image of the first alignment structure with a first wavelength of the light;
forming a second optical image of the second alignment structure with a second wavelength of the visible light; and
aligning the template with the substrate by adjusting a relative displacement of the first and second optical images.

2. The method of claim 1, wherein a refractive index of the top surface of the template is different than a refractive index of the top surface of the substrate.

3. The method of claim 2, wherein the refractive index of the top surface of the template is at least 10% different than the refractive index of the top surface of the substrate.

4. The method of claim 1, wherein a characteristic color of a top surface of the template is different than a characteristic color of the top surface of the substrate.

5. The method of claim 1, wherein a size and dimension of the first alignment structure is substantially identical to the size and dimension of the second alignment structure.

6. The method of claim 1, wherein the light is visible light; and wherein the first wavelength and the second wavelength each comprise a single wavelength or group of wavelengths.

7. The method of claim 1, wherein the first and second alignment structures are illuminated with light comprising a plurality of wavelengths, the method comprising:
filtering the light reflected from the first and second alignment structures using a first filter to form the first optical image; and
filtering the light reflected from the first and second alignment structures using a second filter to form the second optical image.

8. The method of claim 7, wherein the light comprises white light.

9. The method of claim 7, wherein the first and second filters are digital filters.

10. The method of claim 7, wherein the first and second filters are optical filters.

11. The method of claim 7, comprising:
selecting the first and second filters such that the contrast level between the light used to form the first optical image and the light used to form the second optical image exceeds a predetermined threshold.

12. The method of claim 7, comprising:
selecting the first filter such that a wavelength of light used to form the first optical image is substantially equal to a wavelength of light corresponding to a characteristic color of the first alignment structure; and/or
selecting the second filter such that a wavelength of light used to form the second optical image is substantially equal to a wavelength of light corresponding to a characteristic color of the second alignment structure.

13. The method of claim 1, comprising:
illuminating the first and second alignment structures with a first wavelength of light and forming the first optical image from the light reflected from the first and second alignment structures; and
illuminating the first and second alignment structures with a second wavelength of light and forming the second optical image from the light reflected from the first and second alignment structures.

14. The method of claim 1, comprising:
illuminating the first and second alignment structures with a first wavelength of light, and illuminating the first and second alignment structures with a second wavelength of light, wherein reflections of the first wavelength of light and reflections of the second wavelength of light are combined to form the first optical image and/or the reflections of the first wavelength of light and the reflections of the second wavelength of light are combined to form the second optical image.

15. The method of claim 14, comprising:
selecting the first and second wavelengths of light such that a contrast level between the light used to form the first optical image and the light used to form the second optical image exceeds a predetermined threshold.

16. The method of claim 1, wherein the substrate comprises a layer of nano-imprint resist formed over the second alignment structure.

17. The method of claim 16, wherein the layer of nano-imprint resist is substantially photochemically inactive to visible light.

18. The method of claim 1, wherein the aligning comprises:
moving at least one of the template and the substrate to adjust the relative displacement to a desired displacement which is a function of a mask layout of the template.

19. The method of claim 1, wherein the illuminating, forming and aligning are repeated until the relative displacement of the first and second optical images is less than a predetermined value.

20. An alignment apparatus for aligning a lithography template comprising a first alignment structure with a substrate comprising a second alignment structure, the apparatus comprising:
means for simultaneously illuminating the first alignment structure and the second alignment structure with light;
means for forming a first optical image of the first alignment structure using a first wavelength of the light, and for forming a second optical image of the second alignment structure using a second wavelength of the light; and
means for determining a relative position of the first alignment structure and the second alignment structure, and for adjusting the relative position of the lithography template and the substrate based on the relative position of the first and second alignment structures.

21. The apparatus of claim 20, wherein the light is visible light; and wherein the first wavelength and the second wavelength each comprise a single wavelength or group of wavelengths.

22. The apparatus of claim 20, wherein the first and second alignment structures are illuminated with light comprising a plurality of wavelengths, the apparatus comprising:
a first filter to form the first optical image; and
a second filter to form the second optical image.

23. The apparatus of claim 22, wherein the first and second filters are digital filters.

24. The apparatus of claim 22, wherein the first and second filters are optical filters.

25. The apparatus of claim 22, comprising:
selecting the first and second filters such that the contrast level between the light used to form the first optical image and the light used to form the second optical image exceeds a predetermined threshold.
